(19) United States
(12) Patent Application Publication
(10) Pub. No.: US 2020/0227727 A1
(43) Pub. Date: Jul. 16, 2020

(54) High Power Lithium Ion Battery and the Method to Form

(71) Applicant: Weimin Li, New Milford, CT (US)

(72) Inventor: Weimin Li, New Milford, CT (US)

(21) Appl. No.: 16/517,598

(22) PCT Filed: Jan. 19, 2018
(86) PCT No.: PCT/US2018/014416

§ 371 Date: Jul. 21, 2019

Related U.S. Application Data
(60) Provisional application No. 62/448,677, filed on Jan. 20, 2017.

(51) Int. Cl. H01M 4/139; H01M 10/0525; H01M 4/04; H01M 4/36

(52) U.S. Cl. CPC H01M 4/139; H01M 10/0525; H01M 4/0404; H01M 2004/021; H01M 4/0471; H01M 4/043; H01M 4/362

(57) ABSTRACT

A vertical ferroelectric NAND memory system and method of making is disclosed. The vertical ferroelectric NAND memory system may comprise a stack of horizontal layers and a vertical structure. The stack of horizontal layers may be formed on a semiconductor substrate. The stack of horizontal layers may comprise a plurality gate electrode layers alternating with a plurality of insulating layers. The gate electrode layer may comprise conductive lines alternate with insulating lines. The insulating lines may be formed of insulating materials. The conductive lines are formed of a metal comprising W. The vertical structure may extend vertically through the stack of horizontal layers. The vertical structure may comprise a ferroelectric oxide layer, a vertical channel structure. The vertical channel structure may be formed of a semiconductor material.

### RELATED APPLICATIONS

This application claims priority to and benefit from a PCT application No. PCT/US18/14416, which was filed on Jan. 19, 2018, which claims U.S. Provisional Application No. 62/448,677, filed on Jan. 20, 2017, which is hereby incorporated by reference herein in its entirety.

### TECHNICAL FIELD

The present disclosure relates generally to semiconductor devices and non-volatile memory transistor, and more particularly to three-dimensional non-volatile memory devices and methods of fabrications.

### BACKGROUND

A ferroelectric memory has been drawing attention as a nonvolatile memory capable of high-speed operation. The ferroelectric memory is a memory that uses spontaneous polarization of a ferroelectric substance, and includes a capacitor type which is a combination of a transistor and a capacitor, and a transistor type which is used as a gate insulating film of a transistor.

Ferroelectric field effect transistor (FeFET) is a non-volatile memory device which can be built in a vertical configuration. Regardless of whether the FeFETs are integarated as planar two-dimensional or vertical three-dimensional memory transistors, many technological challenges of FeFET memory devices continue to remain. For example, some FeFET memory devices have been known to suffer from limited data retention times (i.e., times associated with change in a polarization state without external power), whose effects have been associated with the presence of a depolarization field.

Therefore, there is a need FeFET memory devices with improved data retention and scalability.

### SUMMARY

According to a first aspect, a method of fabricating three-dimensional NAND comprises steps of forming through the stack of horizontal layers a vertical opening thereby exposing the semiconductor substrate and exposing the stack of horizontal layers on a sidewall of the vertical opening; lining the sidewall of the vertical opening with a vertical ferroelectric oxide layer; forming semiconductor layer over the vertical ferroelectric oxide layer; filling the vertical opening with an insulating material over the semiconductor layer; creating a word line mask on a top surface of the stack; etching unmasked areas through the stacks to form trenches along the word lines; and filling the trenches with the insulating material.

In certain aspects, the method may include forming an interface oxide layer over the vertical ferroelectric oxide layer.

In certain aspects, the semiconductor layer may include polycrystalline silicon.

In certain aspects, the first material may include silicon oxide.

In certain aspects, the second material may be selected from the group consisting of W, Mo, Ru, Ni, Al, Ti, Ta, their nitrides, and the combinations thereof.

In certain aspects, the second material may include W, for example.

In certain aspects, the insulating material may include silicon oxide.

In certain aspects, the layer of the first or second material may be less than about 80 nm thick, for example.

In certain aspects, the layer of the first or second material may be less than about 70 nm thick, for example.

In certain aspects, the layer of the first or second material may be less than about 60 nm thick, for example.

In certain aspects, the layer of the first or second material may be less than about 50 nm thick, for example.

In certain aspects, the second material of the stacks is not completely removed after the formation of the stacks of alternative layers.

In certain aspects, the second material of the stacks is not completely replaced after the formation of the stacks of alternative layers.

In certain aspects, the second material of the stacks is not a sacrificial material.

In certain aspects, the vertical ferroelectric oxide layer may comprise a material selected from the group consisting of Hafnium, Zirconium and the combinations thereof.

According to a second aspect, a vertical ferroelectric memory device may include a stack of horizontal layers, a vertical structure. The stack of horizontal layers may be formed on a semiconductor substrate. The stack of horizontal layers may comprise a plurality gate electrode layers alternating with a plurality of insulating layers. The gate electrode layers may comprise conductive lines alternate with insulating lines. The vertical structure may extend vertically through the stack of horizontal layers. The vertical structure may comprise a ferroelectric oxide layer and a vertical channel structure. The vertical channel structure may be formed of a semiconductor material.

In certain aspects, the ferroelectric oxide layer undergoes a change in polarization state upon application of an electric field between a respective gate electrode layer and the vertical channel structure.

In certain aspects, the vertical ferroelectric memory device may further comprise an interface oxide layer formed over the ferroelectric oxide layer.

In certain aspects, the interface oxide layer may be sandwiched between the vertical channel structure and the ferroelectric oxide layer.

In certain aspects, the conductive lines of the gate electrodes may be formed of a metal.

In certain aspects, the conductive lines of the gate electrodes may be formed of a metal selected from the group consisting of Cu, Al, Ti, W, Ni, Au, TiN, TaN, TaC, NbN, RuTa, Co, Ta, Mo, Pd, Pt, Ru, Ir, Ag and combinations thereof.

In certain aspects, the conductive lines of the gate electrode may be formed of a metal comprising W.

In certain aspects, the ferroelectric oxide layer may comprise a material selected from the group consisting of Hafnium, Zirconium and the combinations thereof.

In certain aspects, the insulating lines may be formed of insulating materials.

In certain aspects, the insulting materials may include silicon oxide.

According to a second aspect, a method of fabricating three-dimensional NAND comprises steps of forming a stack of alternating layers of a first material and a second material over a substrate, wherein the first material comprises a sacrificial material and wherein the second material comprises a conductive material; forming through the stack of horizontal layers a vertical opening thereby exposing the semiconductor substrate and exposing the stack of horizontal layers on a sidewall of the vertical opening; forming a semiconductor layer along the sidewall of the vertical opening and the substrate; filling in an insulating material over the semiconductor layer; filling in an insulating material on the semiconductor layer in the vertical opening; forming through the stack of horizontal layers a vertical opening thereby exposing the semiconductor substrate and exposing the stack of horizontal layers on a sidewall of the vertical opening; selectively removing a part of the second material of the stack through the vertical opening to form a recess; forming a ferroelectric oxide layer along the sidewall of the vertical opening; forming a nitride film on the ferroelectric oxide layer; filling in tungsten into the recess; creating a word line mask on a top surface of the stack; etching unmasked areas through the stacks to form trenches along the word lines; and filling the trenches with the insulating material.

In certain aspects, the semiconductor layer may comprise polycrystalline silicon.

In certain aspects, the sacrificial material may comprise Si₃N₄.

In certain aspects, the second material may be selected from the group consisting of W, Mo, Ru, Ni, Al, Ti, Ta, their nitrides, and the combinations thereof.

In certain aspects, the second material may be preferably W.

In certain aspects, the insulating material may comprise silicon oxide.

In certain aspects, the layer of the first or second material may be less than about 80 nm thick, for example.

In certain aspects, the layer of the first or second material may be less than about 70 nm thick, for example.

In certain aspects, the layer of the first or second material may be less than about 60 nm thick, for example.

In certain aspects, the layer of the first or second material may be less than about 50 nm thick, for example.

In certain aspects, there is no layer between horizontal gate electrode material and vertical ferroelectric material.

### DESCRIPTION OF THE DRAWINGS

These and other advantages of the present invention may be readily understood with the reference to the following specifications and attached drawings wherein:

FIG. 1 illustrates a cross-sectional view of an exemplary three-dimensional ferroelectric oxide memory device in accordance with an aspect of the present disclosure.

FIG. 2 illustrates a cross-sectional view of a stack of alternating layers of a first material and a second material.

FIG. 3 illustrates a flow chart of a method of fabricating a three-dimensional NAND according to one embodiment.

FIG. 4 continually illustrates the flow chart of the method according to FIG. 3.

FIG. 5 illustrates a flow chart of a method of fabricating a three-dimensional NAND according to another embodiment.

FIG. 6 continually illustrates the flow chart of the method according to FIG. 5.

### DETAILED DESCRIPTION

Preferred embodiments of the present disclosure may be described hereinbelow with reference to the accompanying drawings. In the following description, well-known functions or constructions are not described in detail because they may obscure the disclosure in unnecessary detail. For this disclosure, the following terms and definitions shall apply.

Reference throughout this specification to “one embodiment” or “an embodiment” means that a particular feature, structure, or characteristic described in connection with the embodiment is included in at least one embodiment of claimed subject matter. Thus, the appearances of the phrase “in one embodiment” or “an embodiment” in various places throughout this specification are not necessarily all referring to the same embodiment. Furthermore, the particular features, structures, or characteristics may be combined in one or more embodiments.

It will be understood that the terms vertical and horizontal are used herein refer to particular orientations of the figures perpendicular to one another and these terms are not limitations to the specific embodiments described herein.

The terms first, second and the like in the description are used for distinguishing between similar elements and not necessarily for describing a sequential or chronological order. It is to be understood that the terms so used are interchangeable under appropriate circumstances and that the embodiments of the disclosure described herein are capable of operation in other sequences than described or illustrated herein. The terms so used are interchangeable under appropriate circumstances and the embodiments of the disclosure described herein can operate in other orientations than described or illustrated herein.

Additionally, variations to the disclosed embodiments can be understood and effected by the skilled person in practicing the claimed disclosure, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

Also two or more steps may be performed concurrently or with partial concurrence. Further, the steps of the method may be performed in an order different from what has been disclosed. Such variation will depend on the process hardware systems chosen and on designer choice. All such variations are within the scope of the disclosure. Additionally, even though the disclosure has been described with reference to specific exemplifying embodiments thereof, many different alterations, modifications and the like will become apparent for those skilled in the art.

Embodiments include a vertical ferroelectric memory device and methods of making the vertical ferroelectric memory device.

Memories are often configured into arrays to improve density and efficiency. For single transistor memories, the most commonly used array configuration are the NOR and NAND array. Memory technologies such as Flash, EEPROM, EPROM, ROM, PROM, Metal Programmable ROM and Antifuse have all been published using variations of both the NAND and/or NOR array structures. The term NOR or NAND configuration refers to how memory elements are connected in the bit line direction. Typically memory arrays are arranged in rows and columns. When an array is arranged so the memory elements in the column direction directly connect to the same common node/line, the connection is said to be in a NOR configuration. For example, 1-transistor NOR Flash Memory has the column configuration where every memory cell has its drain terminal directly connected to common metal line often called the bit line. Note that in a NOR configuration, care must be taken to ensure that unselected cells within a bit line do not interfere with the reading, write or erase of the selected memory cell. This is often a major complication for arrays configured in the NOR orientation since they all share a single electrically connected bit line.

A NAND connection on the other hand has multiple memory cells connected serially together. A large group of serially connected memory cells may then be connected to a select or access transistor. These access or select devices will then connect to the bit line, source line or both. For example NAND Flash has a select drain gate (SGD) which connects to 32 to 128 serially connected NAND memory cells. NAND Flash also has a second select gate for the source typically called select gate source (SGS). These NAND groupings of SGD, NAND memory cells and SGS are typically referred to as a NAND String. These Strings are connected through the SGD device to the bit line. Note that the SGD device blocks any interaction between the NAND Memory cells within the string to the bit line.

Embodiments of the invention encompass a vertical string or sequence of vertical ferroelectric field effect transistors. More than three transistors, such as metal oxide semiconductor (MOS) would likely be included per string, and many more than six strings, for example, would likely be in a given array (i.e., including a sub-array). Further, vertical strings may be arrayed in other than the side-by-side arrangement. As an example, some or all vertical strings in adjacent rows and/or columns may be diagonally staggered. The discussion proceeds with respect to construction associated with a single vertical string. Vertical string of vertical ferroelectric field effect transistors comprises a string or sequence of metal oxide semiconductor (MOS) structures that share a continuous area of semiconductor, and the oxide between metal and semiconductor has a ferroelectric property.

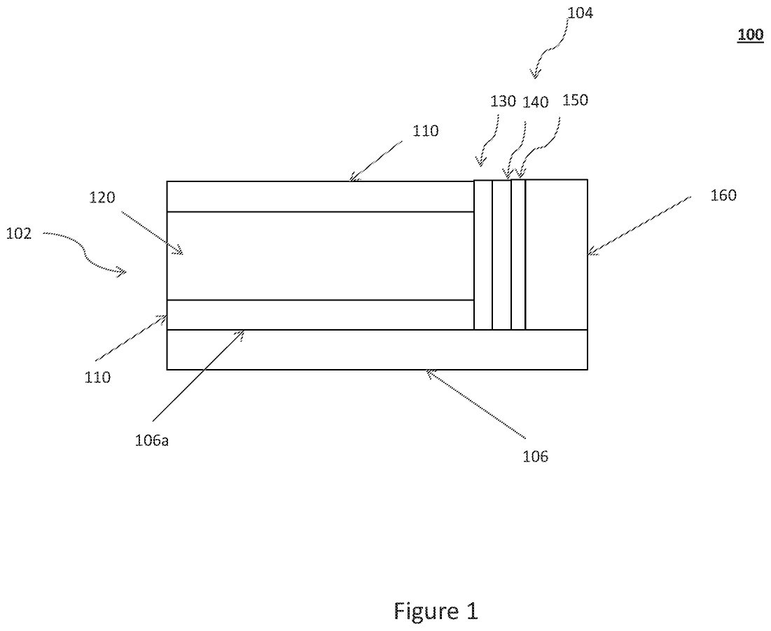

As shown in FIG. 1, a three-dimensional vertical ferroelectric memory device 100 may include a stack of horizontal layers 102, a vertical structure 104. The vertical structure 104 may include a ferroelectric oxide layer 130, and a vertical channel structure 160.

The stack of horizontal layers 102 may be formed on a substrate 106. The stack of horizontal layers 102 may include a plurality gate electrode layers 120 alternating with a plurality of insulating layers 110. The vertical structure 104 may extend vertically through the stack of horizontal layers 102. The vertical channel structure 160 may be formed of a semiconductor material.

The vertical ferroelectric memory device 100 may further include an interface oxide layer 150. The interface oxide layer 150 may be formed over the ferroelectric oxide layer 130. The interface oxide layer 150 may be sandwiched between the vertical channel structure 160 and the ferroelectric oxide layer 130.

Unless explicitly mentioned, when reference is made to ‘the channel region’ or ‘channel structure,’ this also may include source and drain regions. The majority carriers in the source, drain and channel region may thus be the same when applying 0 V to the gate electrodes. The vertical ferroelectric memory device according to the present disclosure is thus a junction-less device, which is advantageous in that few or no depleted regions are present in the memory device. A memory device may be made smaller resulting in a higher cell density. Further, the vertical ferroelectric memory device 100 may become simpler to fabricate and the fabrication costs reduced. Furthermore, the use of junction-less vertical FeFETs provides advantages when using memory cells according to embodiments of the present disclosure in 3D stacked memory structures.

The substrate 106 may be a semiconductor substrate. The substrate 106 can be any semiconducting substrate known in the art, such as monocrystalline silicon, IV-IV compounds such as silicon-germanium or silicon-germanium-carbon, III-V compounds, II-VI compounds, epitaxial layers over such substrates, or any other semiconducting or non-semiconducting material, such as silicon oxide, glass, plastic, metal or ceramic substrate. The substrate 106 may include integrated circuits fabricated thereon, such as driver circuits for a memory device.

Any suitable semiconductor materials can be used for the vertical channel structure 160, for example, silicon, germanium, silicon germanium, a gallium arsenide (GaAs), a gallium arsenide phosphide (GaAsP), an indium phosphide (InP), a germanium (Ge), or a silicon germanium (SiGe) or other compound semiconductor materials, such as III-V, II-VI, or conductive or semiconductive oxides, etc. The semiconductor material may be amorphous, polycrystalline or single crystal. The semiconductor channel material may be formed by any suitable deposition methods. For example, in one embodiment, the vertical channel structure 160 is deposited by low pressure chemical vapor deposition (LPCVD). In some other embodiments, the semiconductor channel material may be a recrystallized polycrystalline semiconductor material formed by recrystallizing an initially deposited amorphous semiconductor material.

In other embodiments, the substrate 106 may include for example, an insulating layer such as a SiO₂ or a Si₃N₄ layer in addition to a semiconductor substrate portion. Thus, the term substrate 106 also includes silicon-on-glass, silicon-on-sapphire substrates. Also, the substrate 106 may be any other base on which a layer is formed, for example a glass or metal layer. Accordingly, a substrate 106 may be a wafer such as a blanket wafer or may be a layer applied to another base material, e.g. an epitaxial layer grown onto a lower layer.

In one embodiment, the vertical ferroelectric memory device 100 may be a monolithic three dimensional memory array. In another embodiment, the memory device 100 may not be a monolithic three dimensional memory array.

A monolithic three dimensional memory array is one in which multiple memory levels are formed above a single substrate, such as a semiconductor wafer, with no intervening substrates. The term “monolithic” means that layers of each level of the array are directly deposited on the layers of each underlying level of the array. In contrast, two dimensional arrays may be formed separately and then packaged together to form a non-monolithic memory device. For example, non-monolithic stacked memories have been constructed by forming memory levels on separate substrates and adhering the memory levels atop each other. The substrates may be thinned or removed from the memory levels before bonding, but as the memory levels are initially formed over separate substrates, such memories are not true monolithic three dimensional memory arrays.

In some embodiments, the vertical channel structure 160 of the vertical ferroelectric memory 100 may have at least one end portion extending substantially perpendicular to a major surface 106a of a substrate 106, as shown in FIG. 1. “Substantially perpendicular to” (or “substantially parallel to”) means within about 0-10°. For example, the vertical channel structure 160 may have a pillar shape and the entire pillar-shaped vertical channel structure extends substantially perpendicularly to the major surface 106a of the substrate 106, as shown in FIG. 1.

Alternatively, the vertical channel structure 160 may have various shapes, which may not be substantially perpendicular to the major surface 106a of the substrate 106. The ferroelectric oxide layer 130, and the interface oxide layer 150 may have various shapes, which may not be substantially perpendicular to the major surface 106a of the substrate 106.

The insulating layer 110 is an isolation layer between two subsequent gate electrode layers 120. The insulating layer 110 may comprise a dielectric material suitable for electrically isolating adjacent electrode layers 120, such as SiOₓ (e.g., SiO₂), SiNₓ (e.g., Si₃N₄), SiOₓN_{y}, Al₂O₃, AN, MgO and carbides or a combination thereof, to name a few. The insulating layer 110 may also comprise low-k dielectric materials such as for example carbon doped silicon oxide, porous silicon oxide, or might be comprising an air or vacuum (airgap) region.

The gate electrode layer 120 may comprise conductive lines alternate with insulating lines. The conductive lines of the gate electrode layer 120 may comprise any conductive material such as, polysilicon or a metal, for example.

The conductive lines of the gate electrode 120 may be formed of a metal, which may be selected from the group consisting of Cu, Al, Ti, W, Ni, Au, TiN, TaN, TaC, NbN, RuTa, Co, Ta, Mo, Pd, Pt, Ru, Ir, Ag and combinations thereof. More preferably, the conductive lines of the metal electrode may be formed of a metal comprising W.

A gate electrode layer 120 can be advantageous over a similar structure formed of a semiconductor material, as metals generally have a lower electrical resistivity compared to many doped semiconductor materials, e.g., doped polysilicon. Moreover, metals offer the low electrical resistivity compared to polysilicon doped to practical levels without a need for high temperature dopant activation. Hence, gate electrode layers 120 are advantageous for charging and discharging the gate capacitance of the memory cell such that a faster device 100 is provided. The use of a metal for forming the conductive lines of the gate electrode layer 120 further removes the carrier depletion effect commonly observed in polysilicon, for example. The carrier depletion effect is also referred to as the poly depletion effect. The reduction of poly depletion effect in the gate electrode layers 120 can be advantageous for improving data retention. Without being bound to any theory, the presence of poly depletion effect can introduce undesirable built-in electrical fields, which can in turn give rise to an undesirable depolarization field in the ferroelectric oxide layer 130 when no external electric field is applied to the gate electrode layers 120.

In addition to reducing the depolarization field arising from the gate electrode layer, it is also desirable to reduce the depolarization field that can arise from depletion effects in the channel layer. The first (reduction of depletion in the channel) may be accomplished with a vertical ferroelectric memory device of the present disclosure by a highly doped channel layer. As discussed above, the latter (reduction of depletion in the gate layer) may be accomplished with a vertical ferroelectric memory device of the present disclosure by using an electrode gate. Upon an application of an electric field between a respective gate electrode layer and the vertical channel structure, the ferroelectric oxide layer undergoes a change in polarization state.

In one embodiment, the insulating lines may be formed of insulating materials. The insulating materials may comprise silicon oxide, for example.

Through the stack 102 of alternating horizontal layers 110 and 120, a vertical structure 104 is present. The vertical structure is substantially perpendicular to the major surface 106a of the substrate 106 and is at least extending through a part of the stack, more preferably throughout the complete stack 102 of alternating horizontal layers 110, 120. The vertical structure 104 has a sidewall 132 along the stack 102 of alternating horizontal layers 110, 120. Depending on the shape of the vertical structure 104, the sidewall 132 may have a different shape. When the vertical structure 104 is a trench, the sidewall 132 has a rectangular shape, i.e. the vertical structure has a rectangular horizontal cross-section from a top view. When the vertical structure 104 has a pillar (cylindrical) shape, the sidewall 132 is cylindrical, i.e. the vertical structure has a circular cross-section from top view.

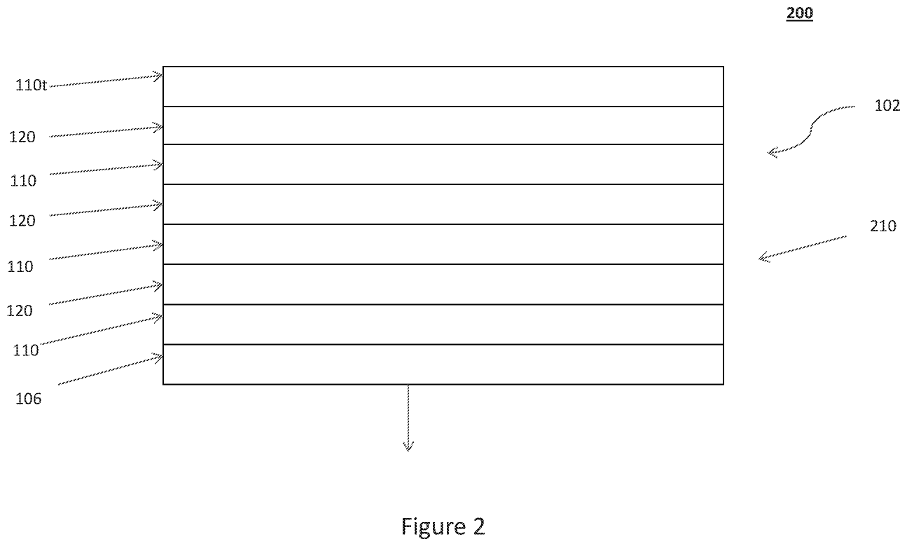

In one embodiment, as shown in FIG. 2, a method 200 of fabricating a three-dimensional NAND, such as the vertical ferroelectric memory device 100 may be carried out by forming a stack of alternative layers 102 of a first material, such as an insulating material/layer 110, for example, and a second material, including a conductive material, such as a gate electrode layer 120, for example, over a substrate 106 in a step 210. In one embodiment, the first material may include silicon oxide, and the second material may be selected from the group consisting of W, Mo, Ru, Ni, Al, Ti, Ta, their nitrides, and the combinations thereof. In another embodiment, the second material may include W, for example. In one embodiment, the second material of the stacks is not completely removed after the formation of the stacks of alternative layers. In another embodiment, the second material of the stacks is not completely replaced after the formation of the stacks of alternative layers. In yet another embodiment, the second material of the stacks is not a sacrificial material.

If desired, a top insulating layer 110t may have a greater thickness and/or a different composition from the other insulating layers 110, shown in FIG. 2. For example, the top insulating layer 110t may comprise a cover silicon oxide layer made using a TEOS source while the remaining layers 110 may comprise thinner silicon oxide layers that may use a different source. In one embodiment, the layer of the first or second material may be less than about 80 nm thick, for example. In one embodiment, the layer of the first or second material may be less than about 70 nm thick, for example. In further embodiment, the layer of the first or second material may be less than about 60 nm thick, for example. In additional embodiment, the layer of the first or second material may be less than about 50 nm thick, for example.

The stack 102 of alternating horizontal layers 110, 120 may be formed using suitable deposition techniques, for example, atomic layer deposition (ALD), physical vapor deposition (PVD), chemical vapor phase deposition (CVD), more preferably, low pressure CVD (LPCVD) or alternatively plasma enhanced CVD (PECVD).

The metal comprising layers described may be deposited in a number of ways, for instance: metal-evaporation, sputtering, chemical vapor deposition (CVD), atomic layer deposition (ALD).

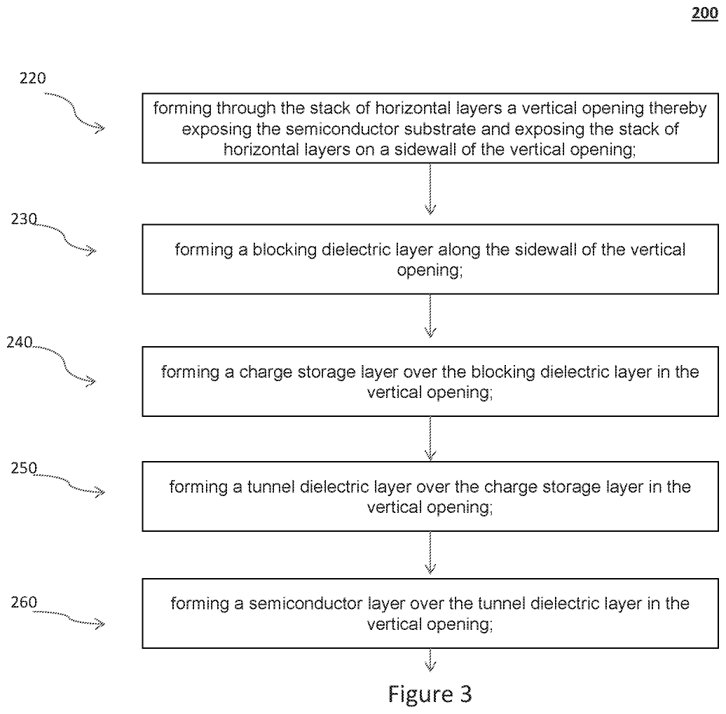

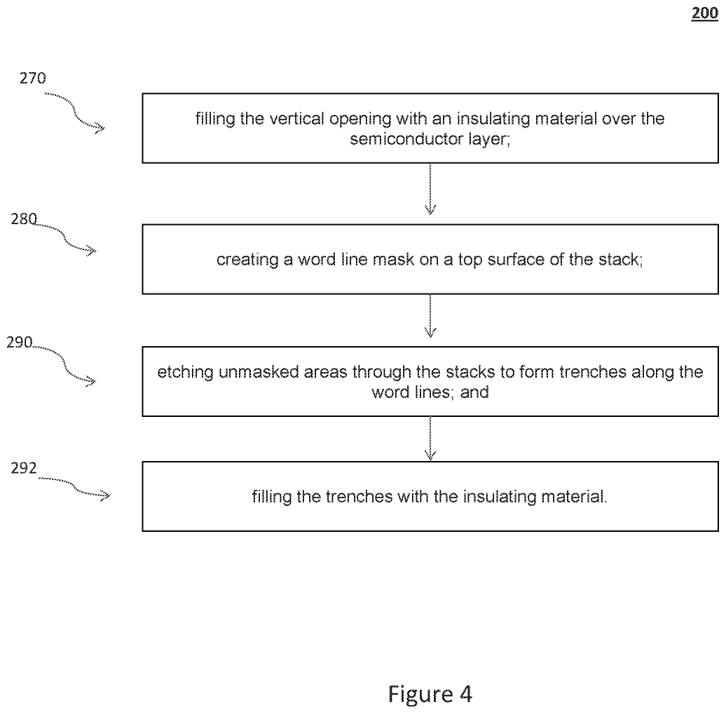

As shown in FIG. 3, the method 200 may be further carried out by forming through the stack of horizontal layers a vertical opening thereby exposing the semiconductor substrate and exposing the stack of horizontal layers on a sidewall of the vertical opening in a step 220, as shown in FIG. 3. The stack of horizontal layers 102 includes a plurality of vertical openings.

In order to fabricate the vertical channel structure 104, a vertical opening or hole may be formed through the stack 102 of alternating horizontal layers 110, 120 (FIG. 2). The vertical opening may be a hole (or pillar or cylinder) or a trench extending through the stack of layers 102. The formation of the vertical opening may be achieved using suitable process techniques such as, for example, the punch process for providing a pillar-like vertical structure of for example patterning and etching for providing a trench-like vertical structure.

The width of the vertical opening (i.e. width of the trench or the diameter of the pillar) is depending on the technology node. The width of the vertical opening may be 120 nm or even smaller, such as 60 nm.

The difference between a trench-like vertical structure and a cylindrical vertical structure (also referred to as gate-all-around (GAA) vertical structure as the gate electrodes are wrapped around the channel region) lies in the amount of bits which can be stored. In case of the trench-like vertical structure, 2 bits may be stored per layer per trench. For a trench at each side of the trench, a bit can be stored, thus 1 bit at the left side wall and 1 bit at the right side wall. In case of the GAA vertical structure, 1 bit may be stored per layer per gate.

After providing the vertical opening, the further layers to complete the vertical ferroelectric memory device 100 may be carried out such as lining the sidewall of the vertical opening with a vertical ferroelectric oxide layer in a step 230; forming semiconductor layer over the vertical ferroelectric oxide layer in a step 240; and filling the vertical opening with an insulating material over the semiconductor layer in a step 250.

One of the features of the vertical ferroelectric memory device 100 according to different embodiments is a vertical ferroelectric oxide layer 130, which is present in the vertical opening, uniform and conformal along the sidewall 132 of the trench. The vertical ferroelectric oxide layer 130 may be directly in contact with the sidewall 132 of the vertical opening, i.e., in direct contact with the gate electrode layers 120 and the insulating layers 110. A vertical ferroelectric layer as described herein may refer to an oxide of one or more transition metals, which includes elements within Groups 3 through 12 in the periodic table.

In one embodiment, the ferroelectric oxide layer may comprise a material selected from the group consisting of Hafnium, Zirconium and the combinations thereof. In some embodiments, the vertical ferroelectric oxide layer 130 comprises a single transition metal oxide such as hafnium oxide (e.g., HfO₂), aluminum oxide (e.g., Al₂O₃), zirconium oxide (e.g., ZrO₂), titanium oxide (e.g., TiO₂), niobium oxide (Nb₂O₅), tantalum oxide (Ta₂O₅), tungsten oxide (WO₃), molybdenum oxide (MO₃), vanadium oxide (V₂O₃) among other single transition metal oxides, to name a few. In other embodiments, the vertical ferroelectric oxide layer 130 may comprise a binary, a ternary, a quaternary or a higher transition metal oxide which includes two, three, four or more metals forming the transition metal oxide.

The vertical ferroelectric oxide layer 130 may be provided using suitable deposition techniques that allow a uniform and conformal deposition of the layer, such as, for example, atomic layer deposition (ALD).

The thickness of the vertical ferroelectric oxide layer 130 may be preferably in the range of 5 nm to 20 nm, for example. Moreover, the thickness of the vertical ferroelectric oxide layer 130 may be tuned depending on the thickness of the vertical channel structure 160.

In retention, when 0 V is applied to the gate electrodes, the equivalent oxide thickness (EOT) of the depletion width in the vertical channel structure 160, summed up with the EOT of the interface oxide layer 150 if present, is desired to be smaller than the thickness of the vertical ferroelectric oxide layer 130. This depletion width depends on the particular engineering of the memory device: if the vertical channel structure 160 is in strong accumulation, for example by engineering the work function of the gate layer 121, the depletion width of this layer is defined by the quantum confinement at the semiconductor-dielectric interface (typically less than 1 nm). If the stack engineering is such that the vertical channel structure 160 is in flatband condition with 0 V applied to the gate electrode, the depletion width is equal to the extrinsic Debye length in the channel layer. The extrinsic Debye length can be determined knowing the semiconductor material and the doping concentration in the vertical channel layer.

According to embodiments, the vertical ferroelectric oxide layer 130 may be doped. The vertical ferroelectric memory device 100 according to one embodiment comprises a HfO₂ ferroelectric layer which is doped with Si, Y, Gd, La, Zr or Al. The vertical ferroelectric oxide layer may thus for example be HfZrO₄, Y:HfO₂, Sr:HfO₂, La:HfO₂, Al:HfO₂ or Gd:HfO₂.

It is an advantage of using a vertical ferroelectric oxide layer, optionally doped, that the layer may be easily formed conformal and uniform along the vertical opening using atomic layer deposition (ALD) techniques. This uniform deposition is difficult with conventional ferroelectric materials used in the prior art such as complex perovskites for example strontium bismuth tantalate (SBT) or lead zirconium titanate (PZT).

It may be a further advantage of using a vertical ferroelectric oxide material, optionally doped, for the vertical ferroelectric layer of a memory device according to embodiments that a replacement gate (RMG) fabrication process may be utilized for manufacturing the memory device. In a RMG fabrication process, the final gate electrodes may be provided after all the vertical layers (i.e. vertical ferroelectric oxide layer, vertical channel structure, vertical interface oxide layer) are provided. The gate electrode layers of the stack of horizontal layers may thus initially be sacrificial layers which are replaced later in the process flow into the final gate electrode layers after providing all the vertical layers (i.e. vertical ferroelectric oxide layer, vertical structure layer, and interface oxide layer).

The vertical ferroelectric oxide layer 130, optionally doped, should have a k-value (k=dielectric constant) lower than the k-value of conventional ferroelectric materials such as perovskites strontium bismuth tantalate (SBT) or lead zirconium titanate (PZT) ferroelectric materials. SBT and PZT typically have a very high-k value (around 250 or higher) such that a very large physical thickness (in order to get a sufficient EOT) would be needed for such material to be used as a ferroelectric layer in a memory device.

The vertical ferroelectric oxide layer 130, optionally doped, may be uniform and conformal along the sidewall of the vertical structure, i.e. the trench or pillar. This means that the vertical ferroelectric oxide layer 130, optionally doped, may be in contact with or overlaps all the horizontal gate electrode layers 120 and all the horizontal insulating layers 110. The vertical ferroelectric oxide layer 130, optionally doped, between the horizontal gate electrode layers 120 and the vertical channel structure 160 may have two possible polarization status. The vertical ferroelectric oxide layer 130, optionally doped, between the horizontal insulating layers 110 and the vertical channel structure 160 may have any polarization status, which might be the same as one of the two polarization statuses in the vertical ferroelectric oxide layer 130, optionally doped, between the horizontal gate electrode layers and the vertical channel structure 160. It may also be a different polarization status, corresponding to a different orientation of the ferroelectric polarization, or even a combination of different random orientations of the polarization. Although the polarization status in this region is not controlled, this will not influence the current through the vertical channel layer because the vertical channel layer is highly doped.

The vertical channel structure 160 may be provided using a suitable deposition technique which enables a uniform and conformal deposition along the vertical ferroelectric oxide layer 130 or the interface oxide layer 150, when present, in the opening, such as ALD, for example. The vertical channel structure 160 may also be provided using a suitable deposition technique such as, for example, chemical vapor deposition (CVD), which enables the vertical channel material to be provided in the remaining part of the vertical opening.

The vertical channel structure 160 may thus be provided in the opening completely filling the opening. Or the vertical channel layer 133 may be provided such that after deposition, there is an opening left, which remaining opening may thereafter be filled with a dielectric filler material. Otherwise said, after providing the vertical ferroelectric oxide layer 130, or after providing the vertical interface layer 150 when present, the core of the vertical opening may be completely filled by the vertical channel structure 160 or may be filled with a uniform (conformal) vertical channel structure 160 along the sidewall thereafter the remaining core of the vertical opening being filled with dielectric filler material.

The dielectric filler material may for example be chosen from Al₂O₃, SiO₂, SiN, air or vacuum (creating an airgap), and a low-k material, to name a few.

The vertical channel region or channel layer of the vertical ferroelectric oxide memory device according to the present disclosure may be highly doped. This is necessary to get a so-called pinch-off effect in the memory device. Different possible interpretations of ‘highly doped’ will now be elaborated.

When 0 V is applied to the gate electrode layers, independent of the polarization state of the vertical ferroelectric layer, the concentration of majority carriers in the channel region being responsible for the doping of the channel region should be much larger than the minority carriers. Much larger means at least 104 times larger, or more than 104 times larger when the channel region material is for example Si, Ge, GaAs or another semiconductor with bandgap larger than 0.6 eV. The difference in concentration between majority and minority carriers can however be smaller when the channel material is a narrow bandgap semiconductor such as InAs or InSb.

If the vertical channel structure is for example silicon doped with As, the majority carriers are electrons. The concentration of these majority carriers (electrons) should thus be at least 104 times larger than the concentration of holes in the channel region. If the vertical channel region or channel layer is for example silicon doped with B, the majority carriers are holes. The concentration of these majority carriers (holes) should thus be at least 104 times larger than the concentration of electrons in the channel region.

On the other hand, the doping concentration should also not be too high in order to allow that the channel still can be depleted by the gate control voltage in order to turn off the memory cell (which is at a negative voltage applied to the gate electrode layer for n-type, and at positive voltage applied to the gate electrode for p-type). The doping concentration in the channel region is preferably in a range between 1.0×10¹⁸ dopants/cm³ and 1×10²⁰ dopants/cm³, between 1.0×10¹⁹ dopants/cm³ and 1×10²⁰ dopants/cm³, between 1.0×10¹⁸ dopants/cm³ and 2×10¹⁹ dopants/cm³, or between 1.0×10¹⁹ dopants/cm³ and 2×10¹⁹ dopants/cm³.

Furthermore, the combined effect of the doping concentration in the vertical channel region and engineering the gate layer should be such that the EOT of the effective depletion width of the vertical channel structure is lower than the EOT of the ferroelectric oxide layer. This can be obtained by choosing both such that the surface of the vertical channel region is in strong accumulation when 0 V is applied on the gate.

Alternatively, the doping concentration in the vertical channel region can be such that the ratio of the extrinsic Debye length to the relative permittivity of the channel material is smaller than the ratio of the thickness of the vertical ferroelectric layer to the relative permittivity of the ferroelectric layer. In this case, it is sufficient that the vertical channel region is near flatband condition when 0 V is applied on the gate layer.

Summarized, the channel structure 160 of a vertical ferroelectric memory device 100, according to different embodiments of the present disclosure, has the following features, according to embodiments: Source, drain and channel region (not the contact region) are uniformly doped, such that they have a same doping type and, preferably, a same doping concentration. A higher doping concentration in that part of the source and/or drain regions which serve as the contact regions of the device. The contact regions are far remote from the channel region. These contact regions are thus not taken into consideration for the channel region.

The vertical channel structure (which may include source and drain) may be highly doped such that when a gate voltage of 0 V is applied to the gate electrodes (i.e. the device is idle/at rest) the channel layer is not in depletion, but remains conductive.

Furthermore, the channel region has one or more of the following features, according to embodiments: The channel region may be in accumulation when a gate voltage of 0 V is applied to the gate electrodes (i.e. the device is idle/in rest) due to suitable work function of the gate electrodes.

The channel structure may be sufficiently highly doped such that the ratio of the extrinsic Debye length to the relative permittivity of the channel material is smaller than the ratio of the thickness of the vertical ferroelectric layer to the relative permittivity of the ferroelectric layer.

The extrinsic Debye length is a criterion for the depletion of the device at flatband condition.

The method 200 may be further carried out by creating a word line mask on a top surface of the stack in a step 260. The method 200 may be carried out by etching unmasked areas through the stacks to form trenches along the word lines in a step 270 and filling the trenches with the insulating material in a step 280. The word lines are substantially perpendicular to bit lines. In one embodiment, the masking material may comprise silicon oxide, for example. In one embodiment, parallel trenches were created through the stacks of alternating layers of first material and a second material. Insulating materials, such as polycrystalline silicon, for example, may be filled and thus parallel conductive lines may be formed for each alternating layers.

The method 200 may be further carried out by chemical mechanical polishing (CMP) to remove the semiconductor layer on the top surface of the stack and planarizing the top surface after the chemical mechanical polishing. The removal may be conducted by selectively wet etching the remaining nucleation promoter layer and any formed silicide in the top of layer following by CMP of the top of silicon layer using the top of the stacks as a stop.

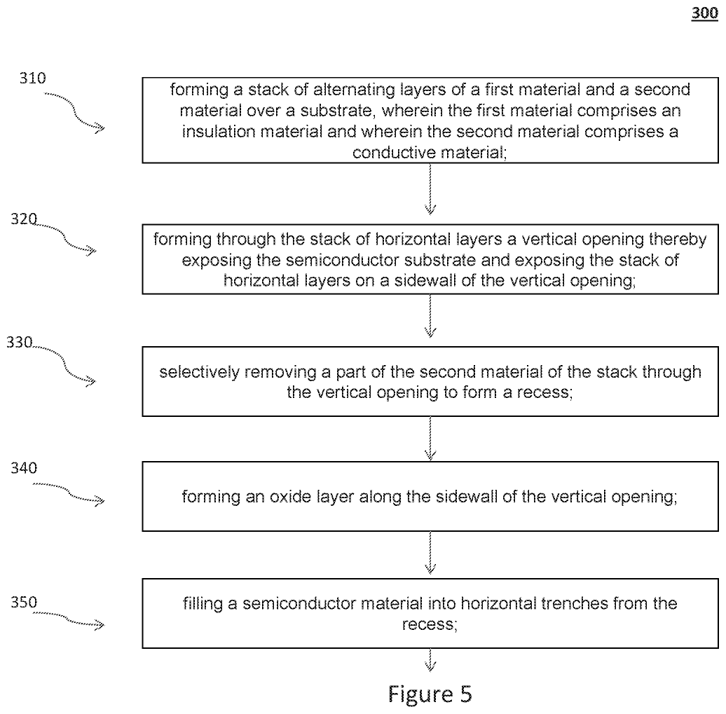

In another embodiment, as shown in FIG. 5, a method 300 of fabricating a three-dimensional NAND may be carried out by forming a stack of alternating layers of a first material 310 and a second material 320 over a substrate 306. The first material 310 may comprise an insulation material. The second material 320 may comprise a sacrificial material in a step 330. If desired, a top insulating layer 310t may have a greater thickness and/or a different composition from the other insulating layers 310, shown in FIG. 2.

The method 300 may be further carried out by forming through the stack of horizontal layers a vertical opening 332 thereby exposing the semiconductor substrate 306 and exposing the stack of horizontal layers on a sidewall 336 of the vertical opening in a step 340.

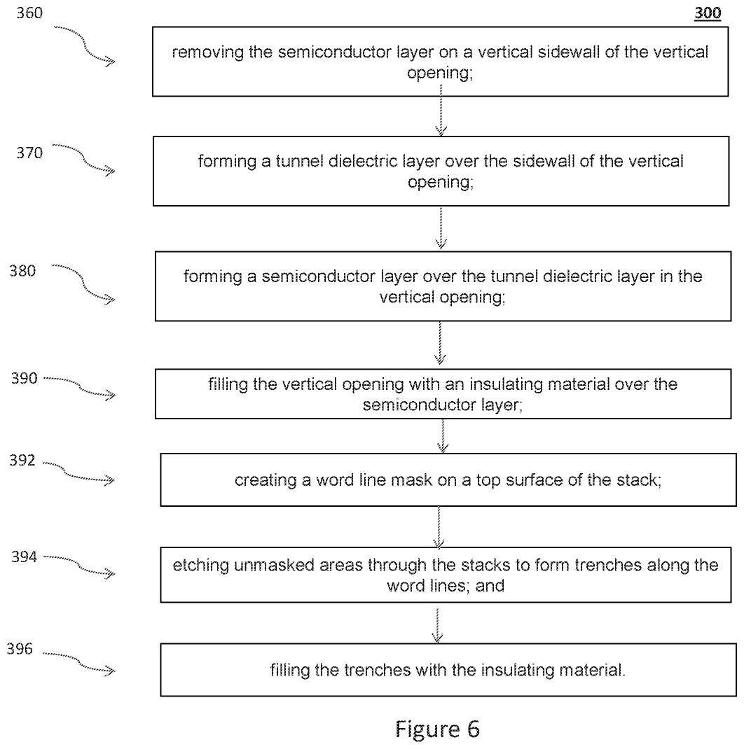

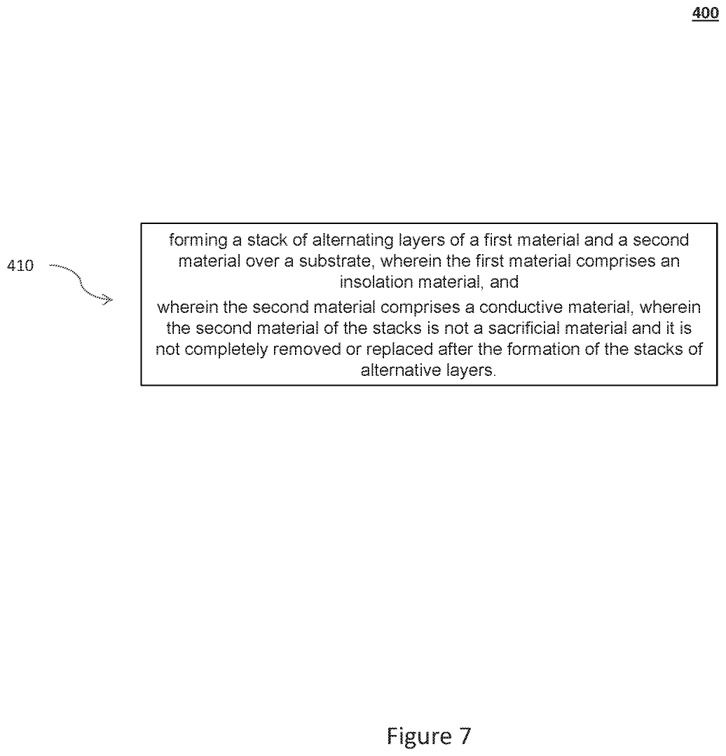

As shown in FIG. 6, the method 300 may be further carried out by forming a semiconductor material layer 352 along the sidewall 336 and substrate 306 of the vertical opening 332 and filling an insulating layer 356 over the semiconductor material layer 352 in a step 350. In one embodiment, the semiconductor material layer 352 may include polycrystalline silicon, for example. The insulating layer 356 may include silicon oxide, for example.

The method 300 may be further carried out by forming through the stack of horizontal layers a vertical opening thereby exposing the semiconductor substrate and exposing the stack of horizontal layers on a sidewall of the vertical opening. The vertical opening may be filled in with an insulating material, such as silicon oxide, for example.

The method 300 may further include a step of forming through the stack of horizontal layers a vertical opening thereby exposing the semiconductor substrate, exposing the stack of horizontal layers on a sidewall of the vertical opening, and selectively removing a part of the second material, such as the sacrificial material, of the stack through the vertical opening to form a recess. The selectively removing a part of the second material may be done via a wet etch, such as wet chemical etch. The method 300 may be further carried out by forming a ferroelectric oxide layer along the sidewall of the vertical opening. The method 300 may be further carried out by depositing a nitride film over the ferroelectric layer and depositing W in the recess. The nitride, such as titanium nitride, or other suitable dielectrics may be deposited using atomic layer deposition (ALD) or chemical vapor deposition (CVD). W may be deposited using atomic layer deposition (ALD) or chemical vapor deposition (CVD).

The method 300 may be further carried out by creating a word line mask on a top surface of the stack. The method 300 may be carried out by etching unmasked areas through the stacks to form trenches along the word lines and filling the trenches with the insulating material. The word lines are substantially perpendicular to bit lines. In one embodiment, the masking material may comprise silicon oxide, for example. In one embodiment, parallel trenches were created through the stacks of alternating layers of first material and a second material. Insulating materials, such as polycrystalline silicon, for example, may be filled and thus parallel conductive lines may be formed for each alternating layers.

The method 300 may be further carried out by chemical mechanical polishing (CMP) to remove the semiconductor layer on the top surface of the stack and planarizing the top surface after the chemical mechanical polishing. The removal may be conducted by selectively wet etching the remaining nucleation promoter layer and any formed silicide in the top of layer following by CMP of the top of silicon layer using the top of the stacks as a stop.

The above-cited patents and patent publications are hereby incorporated by reference in their entirety. Although various embodiments have been described with reference to a particular arrangement of parts, features, and like, these are not intended to exhaust all possible arrangements or features, and indeed many other embodiments, modifications, and variations may be ascertainable to those of skill in the art. Thus, it is to be understood that the invention may therefore be practiced otherwise than as specifically described above.

1. A lithium ion battery comprising:
an anode comprising a negative electrode material and a negative current collector;
a cathode comprising a positive electrode material and a positive current collector, wherein the negative or positive electrode material forms a continuous negative or positive electrode material layer on the negative or positive current collector; and
a separator separating the anode and the cathode, wherein at least one continuous electrode material layer includes a plurality of vertical structures having
depths into the current collector, the plurality of the vertical structures are configured in an array, and
sidewalls defining the plurality of vertical structures.

2. The lithium ion battery of claim 1, wherein the array is hexagonal.

3. The lithium ion battery of claim 1, wherein the continuous negative or positive electrode material layer has a thickness from about 50 microns to about 300 microns.

4. The lithium ion battery of claim 1, wherein the continuous negative or positive electrode material layer has a thickness from about 80 microns to 300 microns.

5. The lithium ion battery of claim 1, wherein the continuous negative or positive electrode material layer has a thickness from about 100 microns to 300 microns.

6. The lithium ion battery of claim 1, wherein the continuous negative or positive electrode material layer has a thickness from about 150 microns to 300 microns.

7. The lithium ion battery of claim 1, wherein the depth of the vertical structure is from about 25 microns to about 250 microns.

8. The lithium ion battery of claim 1, wherein the depth of the vertical structure is about 100 microns.

9. The lithium ion battery of claim 1, wherein the vertical structures are spaced from about 50 microns to about 500 microns.

10. The lithium ion battery of claim 1, wherein the vertical structures are spaced from about 100 microns to about 400 microns.

11. The lithium ion battery of claim 1, wherein the vertical structures are spaced from about 200 microns to about 300 microns.

12. The lithium ion battery of claim 1, wherein the lithium ion battery has a high-power capacity of 180 Wh/kg at a charging rate of 6 C.

13. A method of preparing an electrode, comprising:
providing a current collector;
mixing an active material, binder, and conductive materials to form a mixture;
putting the mixture through a screen, wherein the screen has a plurality of openings, wherein the plurality of openings is configured in an array and is surrounded by a plurality of sidewalls;
coating one side of the current collector with the screened mixture to form a coated current collector;
pressing and heating the coated current collector to form a dried coated current collector; and
cutting the dried coated current collector to a predetermined size.

14. The method of claim 13, wherein the array is hexagonal.

15. The method of claim 13, wherein the plurality of sidewalls have heights from about 25 microns to about 250 microns.

16. The method of claim 13, wherein the plurality of sidewalls have heights from about 50 microns to about 200 microns.

17. The method of claim 13, wherein the plurality of sidewalls have heights from about 100 microns to about 150 microns.

18. The method of claim 13, wherein the plurality of sidewalls have heights about 100 microns.

19. The method of claim 13, wherein the openings are spaced from about 50 microns to about 500 microns.

20. The method of claim 13, wherein the openings are spaced from about 100 microns to about 400 microns.

21. The method of claim 13, wherein the openings are spaced from about 200 microns to about 300 microns.

22. A method of preparing an electrode, comprising:
providing a current collector;
mixing an active material, binder, and conductive materials to form a mixture;
coating one side of the current collector with the mixture to form a coated current collector;
forming a plurality of vertical structures on the coated current collector by stamping, or drilling, wherein the plurality of vertical structure have depths into the current collector, the plurality of the vertical structures are configured in an array; and
cutting the coated current collector to a predetermined size.

23. The method of claim 22, wherein the array is hexagonal.

24. The method of claim 22, wherein the depths are from about 25 microns to about 250 microns.

25. The method of claim 22, wherein the depths are from about 50 microns to about 200 microns.

26. The method of claim 22, wherein the depths are from about 100 microns to about 150 microns.

27. The method of claim 22, wherein the depths are about 100 microns.

28. The method of claim 22, wherein the plurality of vertical structures are spaced from about 50 microns to about 500 microns.

29. The method of claim 22, wherein the plurality of vertical structures are spaced from about 100 microns to about 400 microns.

30. The method of claim 22, wherein the plurality of vertical structures are spaced from about 200 microns to about 300 microns.

31. The method of claim 22 further comprising heating the coated current collector before forming a plurality of vertical structures.

32. The method of claim 22 further comprising heating the coated current collector after forming a plurality of vertical structures.

33. The method of claim 22 further comprising heating the coated current collector while forming a plurality of vertical structures.

34. The method of claim 22 further comprising pressing the coated current collector before forming a plurality of vertical structures.

35. The method of claim 22 further comprising pressing the coated current collector after forming a plurality of vertical structures.

36. The method of claim 22 further comprising pressing the coated current collector while forming a plurality of vertical structures.

37. The method of claim 22, wherein the drilling comprises a jet drilling or a laser drilling.

38. A method of preparing an electrode, comprising:
providing a current collector;
mixing an active material, binder, and conductive materials to form a mixture;
putting the mixture through an array of nozzles, and onto one side of the current collector with the mixture to form a coated current collector with a plurality of vertical structures on the coated current collector, wherein the plurality of vertical structure have depths into the current collector;
forming the plurality of the vertical structures are configured in an array; and
cutting the coated current collector to a predetermined size.

39. The method of claim 38, wherein the array is hexagonal.

40. The method of claim 38, wherein the depths are from about 25 microns to about 250 microns.

41. The method of claim 38, wherein the depths are from about 50 microns to about 200 microns.

42. The method of claim 38, wherein the depths are from about 100 microns to about 150 microns.

43. The method of claim 38, wherein the depths are about 100 microns.

44. The method of claim 38, wherein the plurality of vertical structures are spaced from about 50 microns to about 500 microns.

45. The method of claim 38, wherein the plurality of vertical structures are spaced from about 100 microns to about 400 microns.

46. The method of claim 38, wherein the plurality of vertical structures are spaced from about 200 microns to about 300 microns.
